(19) United States
(12) Patent Application Publication
(10) Pub. No.: US 2021/0159058 A1
(43) Pub. Date: May 27, 2021

(54) THERMAL CONDUCTIVE MEMBER, PLASMA PROCESSING APPARATUS, AND VOLTAGE CONTROL METHOD

(71) Applicant: Tokyo Electron Limited, Tokyo (JP)

(72) Inventor: Yusei Kuwabara, Kurokawa-gun (JP)

(21) Appl. No.: 16/951,005

(22) Filed: Nov. 18, 2020

(30) Foreign Application Priority Data
Nov. 22, 2019 (JP) 2019-211578

(51) Int. Cl. H01J 37/32

(52) U.S. Cl. CPC H01J 37/32724; H01J 37/32642

(57) ABSTRACT

Provided is a thermal conductive member that can stably transfer heat and can be easily maintained. The thermal conductive member is provided in a plasma processing apparatus, the plasma processing apparatus including: a first electrostatic chuck on which a substrate is mounted in a chamber that provides a plasma processing space; a second electrostatic chuck provided on an outer periphery of the first electrostatic chuck; an edge ring which is provided on the second electrostatic chuck so as to surround a region on which the substrate is mounted and at least a portion of which is made of a conductive member; and an electrode for edge ring to which a voltage for electrostatically attracting the edge ring is applied in a region corresponding to the edge ring inside the second electrostatic chuck, in which the thermal conductive member is arranged between the second electrostatic chuck and the edge ring.

### CROSS-REFERENCE TO RELATED APPLICATIONS

This application claims the benefit of Japanese Patent Application No. 2019-211578 filed on Nov. 22, 2019, the entire disclosure of which is incorporated herein by reference.

### TECHNICAL FIELD

The present disclosure relates to a thermal conductive member, a plasma processing apparatus, and a voltage control method.

### BACKGROUND ART

For example, JP-A-2008-16727 proposes a plasma processing apparatus in which a thermal conductive sheet made of a gel-like material is arranged between an electrostatic chuck and a focus ring. The thermal conductive sheet has adhesiveness.

### SUMMARY

The disclosure provides a thermal conductive member that can stably transfer heat and can be easily maintained.

According to one aspect of the disclosure, there is provided a thermal conductive member provided in a plasma processing apparatus, the plasma processing apparatus including: a first electrostatic chuck on which a substrate is mounted in a chamber that provides a plasma processing space; a second electrostatic chuck which is provided on an outer periphery of the first electrostatic chuck; an edge ring which is provided on the second electrostatic chuck so as to surround a region on which the substrate is mounted and at least a portion of which is made of a conductive member; and an electrode for edge ring to which a voltage for electrostatically attracting the edge ring is applied in a region corresponding to the edge ring inside the second electrostatic chuck, in which the thermal conductive member is arranged between the second electrostatic chuck and the edge ring.

According to one aspect, it is possible to provide a thermal conductive member that can stably transfer heat and can be easily maintained.

### BRIEF DESCRIPTION OF DRAWINGS

FIG. 1 is a schematic cross-sectional view illustrating an example of a plasma processing apparatus according to an embodiment;

FIG. 2 is an enlarged view of a portion of an interface of a thermal conductive member according to an embodiment;

FIG. 3 is a diagram illustrating an example of a relationship between a thickness of the thermal conductive member (sheet) and an attraction force according to the embodiment;

FIG. 4 is a diagram illustrating Modified Example of configurations of the thermal conductive member and an electrostatic chuck according to the embodiment;

FIG. 5 is a flowchart illustrating an example of a voltage control method according to an embodiment; and

FIGS. 6A to 6C are diagrams for describing the voltage control method according to the embodiment.

### DESCRIPTION OF EMBODIMENTS

Hereinafter, modes for carrying out the disclosure will be described with reference to the drawings. In some cases, in each figure, the same components may be denoted by the same reference numerals, and redundant description may be omitted.

[Plasma Processing Apparatus]

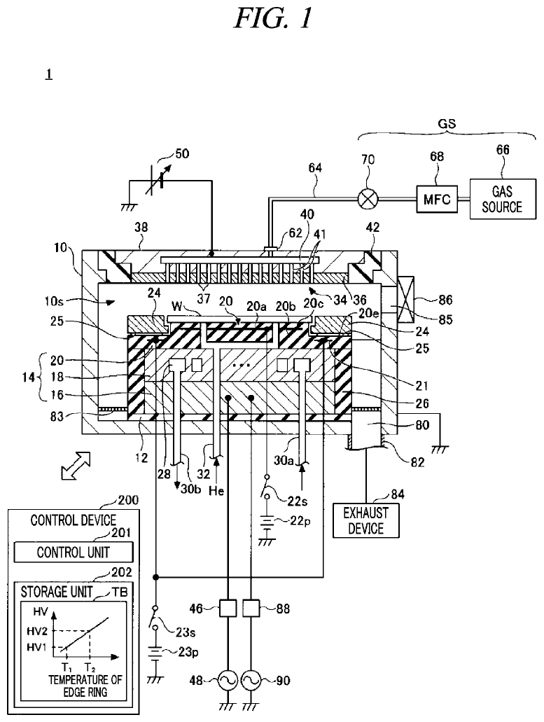

A plasma processing apparatus 1 according to the embodiment will be described with reference to FIG. 1. FIG. 1 is a schematic cross-sectional view illustrating an example of the plasma processing apparatus according to the embodiment.

The plasma processing apparatus includes a chamber 10. The chamber 10 provides a plasma processing space 10s. The chamber 10 has a substantially cylindrical shape. The chamber 10 is made of, for example, aluminum. A film having corrosion resistance is provided on an inner wall surface of the chamber 10. The film may be made of a ceramic such as aluminum oxide or yttrium oxide.

A passage 85 is formed in a side wall of the chamber 10. A substrate W is transferred between the plasma processing space 10s and the outside of the chamber 10 through the passage 85. The passage 85 is opened and closed by a gate valve 86 provided along the side wall of the chamber 10.

A cylindrical support portion 26 is arranged at the bottom of the chamber 10 via an insulating plate 12 made of a material such as ceramic. A substrate support 14 is supported on the insulating plate 12 by the support portion 26. The substrate support 14 is configured so as to support the substrate W in the plasma processing space 10s.

The substrate support 14 has a lower electrode 18 and an electrostatic chuck 20. The substrate support 14 may further have an electrode plate 16. The electrode plate 16 is made of a conductor such as aluminum and has a substantially disc shape. The lower electrode 18 is provided on the electrode plate 16. The lower electrode 18 is made of a conductor such as aluminum and has a substantially disc shape. The lower electrode 18 is electrically connected to the electrode plate 16.

The electrostatic chuck 20 is provided on the lower electrode 18. The substrate W is mounted on the upper surface of the electrostatic chuck 20. The electrostatic chuck 20 has a first electrostatic chuck 20c on the side (center) where the substrate W is arranged and a second electrostatic chuck 20e provided on the side (outer periphery) of the first electrostatic chuck 20c where an edge ring 24 is arranged. In the embodiment, the first electrostatic chuck 20c and the second electrostatic chuck 20e are integrated, but the invention is not limited thereto, and the first and second electrostatic chucks may be separate components. Hereinafter, the first electrostatic chuck 20c and the second electrostatic chuck 20e are also collectively referred to as the electrostatic chuck 20. The electrostatic chuck 20 has an electrode 20a for substrate and a main body 20b. The main body 20b has a substantially disc shape and is made of a dielectric material. The electrode 20a for substrate is a film-shaped electrode and is provided inside the main body 20b. The electrode 20a for substrate is connected to a power supply 22p via a switch 22s. When a DC voltage (hereinafter, also referred to as “HV voltage”) from the power supply 22p is applied to the electrode 20a for substrate, an electrostatic attraction force is generated between the electrostatic chuck 20 and the substrate W. Due to the electrostatic attraction force, the substrate W is held on the electrostatic chuck 20.

The edge ring 24 is arranged on the mounting surface of the second electrostatic chuck 20e, which is provided at a step on the periphery of the main body 20b, so as to surround the edge of the substrate W. The edge ring 24 is also referred to as a focus ring. The edge ring 24 improves in-plane uniformity of plasma processing on the substrate W. At least a portion of the edge ring 24 may be configured with a conductive member and may be made of silicon (Si), silicon carbide (SiC), quartz, or the like.

An electrode 21 for edge ring to which a voltage for electrostatically attracting the edge ring 24 is applied is provided in a region corresponding to the edge ring 24 inside the second electrostatic chuck 20e. The electrode 21 for edge ring is a film-shaped electrode provided in a ring shape below the edge ring 24 inside the main body 20b. The electrode 21 for edge ring is connected to a power supply 23p via a switch 23s. When a DC voltage (hereinafter, also referred to as an “HV voltage”) from the power supply 23p is applied to the electrode 21 for edge ring, an electrostatic attraction force is generated between the electrostatic chuck 20 and the edge ring 24. Due to the electrostatic attraction force, the edge ring 24 is held on the electrostatic chuck 20. A thermal conductive member 25 is arranged between the edge ring 24 and the main body 20b.

A flow channel 28 is provided inside the lower electrode 18. A heat exchange medium (cooling medium and heating medium) for temperature adjustment is supplied to the flow channel 28 from a chiller unit (not illustrated) provided outside the chamber 10 via a pipe 30a. The heat exchange medium supplied to the flow channel 28 is returned to the chiller unit via a pipe 30b. In the plasma processing apparatus 1, the temperature of the substrate W mounted on the electrostatic chuck 20 is adjusted by heat exchange between the heat exchange medium and the lower electrode 18.

A gas supply line 32 is provided to the plasma processing apparatus 1. The gas supply line 32 supplies a heat transfer gas (for example, He gas) from a heat transfer gas supply mechanism (not illustrated) between the upper surface of the electrostatic chuck 20 and the lower surface of the substrate W.

The plasma processing apparatus 1 further includes an upper electrode 34. The upper electrode 34 is provided above the substrate support 14. The upper electrode 34 is supported on the upper portion of the chamber 10 via an insulating member 42 and closes the upper opening of the chamber 10.

The upper electrode 34 has a top plate 36 and a support 38. The lower surface of the top plate 36 is the lower surface on the side of the plasma processing space 10s and defines the plasma processing space 10s. The top plate 36 may be made of a low-resistance conductor or semiconductor that generates a small amount of Joule heat. The top plate 36 has a plurality of gas ejection holes 37 that penetrate the top plate 36 in the plate thickness direction.

The support 38 detachably supports the top plate 36. The support 38 is made of a conductive material such as aluminum. A gas diffusion chamber 40 is provided inside the support 38. The support 38 has a plurality of gas holes 41 extending downward from the gas diffusion chamber 40. The plurality of gas holes 41 communicate with the plurality of gas ejection holes 37, respectively. A gas introduction hole 62 is formed in the support 38. The gas introduction hole 62 is connected to the gas diffusion chamber 40. The gas introduction hole 62 is connected to a gas supply pipe 64.

A valve group 70, a flow rate controller group 68, and a gas source group 66 are connected to the gas supply pipe 64. The gas source group 66, the valve group 70, and the flow rate controller group 68 constitute a gas supply unit GS. The gas source group 66 includes a plurality of gas sources. The valve group 70 includes a plurality of opening/closing valves. The flow rate controller group 68 includes a plurality of flow rate controllers. Each of the plurality of flow rate controllers of the flow rate controller group 68 is a mass flow controller or a pressure control type flow rate controller. Each of the plurality of gas sources of the gas source group 66 is connected to the gas supply pipe 64 via a corresponding flow rate controller of the flow rate controller group 68 and a corresponding opening/closing valve of the valve group 70.

In the plasma processing apparatus 1, a shield (not illustrated) is detachably provided along the inner wall surface of the chamber 10 and the outer periphery of the support portion 26. A baffle plate 83 is provided between the support portion 26 and the side wall of the chamber 10. The baffle plate 83 is configured, for example, by forming a film (a film of such as yttrium oxide) having corrosion resistance on the surface of a base material made of aluminum. A plurality of through holes are formed in the baffle plate 83. An exhaust port 80 is provided below the baffle plate 83 and at the bottom of the chamber 10. An exhaust device 84 is connected to the exhaust port 80 via an exhaust pipe 82. The exhaust device 84 includes a pressure adjustment valve and a vacuum pump such as a turbo molecular pump.

The plasma processing apparatus 1 includes a first radio frequency power supply 48 and a second radio frequency power supply 90. The first radio frequency power supply 48 generates a first radio frequency power. The first radio frequency power has a frequency suitable for plasma generation. The frequency of the first radio frequency power is a frequency within the range of, for example, 27 MHz to 100 MHz. The first radio frequency power supply 48 is connected to the lower electrode 18 via a matching unit 46 and the electrode plate 16. The matching unit 46 has a circuit for matching the output impedance of the first radio frequency power supply 48 with the impedance of the load side (lower electrode 18 side). In addition, the first radio frequency power supply 48 may be connected to the upper electrode 34 via the matching unit 46.

The second radio frequency power supply 90 generates a second radio frequency power. The second radio frequency power has a frequency lower than the first radio frequency. In a case where the second radio frequency power is used together with the first radio frequency power, the second radio frequency power is used as the bias voltage for attracting the ions into the substrate W. The frequency of the second radio frequency power is a frequency within the range of, for example, 400 kHz to 13.56 MHz. The second radio frequency power supply 90 is connected to the lower electrode 18 via a matching unit 88 and the electrode plate 16. The matching unit 88 has a circuit for matching the output impedance of the second radio frequency power supply 90 with the impedance of the load side (lower electrode 18 side).

In addition, the plasma may be generated by using the second radio frequency power without using the first radio frequency power, that is, by using only the single radio frequency power. In this case, the plasma processing apparatus 1 may not include the first radio frequency power supply 48 and the matching unit 46, and the frequency of the second radio frequency power may be a frequency higher than 13.56 MHz, for example, 40 MHz.

In the plasma processing apparatus 1, gas is supplied from the gas supply unit GS to the plasma processing space 10s to generate plasma. In addition, by supplying the first radio frequency power and/or the second radio frequency power, a radio frequency electric field is generated between the upper electrode 34 and the lower electrode 18. The generated radio frequency electric field generates plasma.

The plasma processing apparatus 1 includes a power supply 50. The power supply 50 is connected to the upper electrode 34. The power supply 50 applies to the upper electrode 34 a voltage for drawing the positive ions contained in the plasma processing space 10s into the top plate 36. The power supply 50 may generate negative direct current voltage (negative DC voltage).

The plasma processing apparatus 1 may further include a control device 200. The control device 200 is a computer including a control unit 201 such as a processor and a storage unit 202 such as a memory. The control unit 201 controls each unit of the plasma processing apparatus 1. The storage unit 202 stores a control program and recipe data. The control program is executed by the control unit 201 to perform various processes in the plasma processing apparatus 1. The control unit 201 executes the control program and controls each unit of the plasma processing apparatus 1 according to the recipe data.

In addition, the storage unit 202 stores information indicating correlation between a temperature of the edge ring 24 and an HV voltage applied to the electrode 21 for edge ring in a table TB. In order to electrostatically attract the edge ring 24 to the electrostatic chuck 20, it is necessary to control the HV voltage applied to the electrode 21 for edge ring according to the temperature of the edge ring 24. For example, when the temperature of the edge ring 24 is increased, the HV voltage applied to the electrode 21 for edge ring is increased in order to increase the electrostatic attraction force. For this reason, the appropriate value of the HV voltage required to electrostatically attract the edge ring 24 to the electrostatic chuck 20 with respect to the temperature of the edge ring 24 is measured in advance. Then, the information indicating the correlation between the temperature of the edge ring 24 and the HV voltage obtained as a result of the measurement is stored in the table TB. The temperature of the edge ring 24 is measured by a temperature sensor 29 arranged at the bottom of the edge ring 24 and transmitted to the control device 200. The control unit 201 refers to the table TB stored in the storage unit 202 and controls the HV voltage applied to the electrode 21 for edge ring according to the measured temperature of the edge ring 24.

[Thermal Conductive Member]

The thermal conductive member 25 is arranged between the electrostatic chuck 20 and the edge ring 24 and has a sheet shape. However, the thermal conductive member 25 is not limited to the sheet shape and may be, for example, a gel material.

The thermal conductive member 25 is a high dielectric material formed by adding a high dielectric material to silicon and alumina (Al₂O₃). However, the thermal conductive member 25 may use silicon carbide or tungsten carbide (WC), which is harder than silicon, instead of silicon. For example, the thermal conductive member 25 may be a high dielectric material formed by adding a high dielectric material to silicon carbide and alumina (Al₂O₃) or may be a high dielectric material formed by adding a high dielectric material to tungsten carbide and alumina (Al₂O₃).

The thermal conductive member 25 does not have adhesiveness. That is, the thermal conductive member 25 having a high permittivity and no adhesiveness is arranged between the electrostatic chuck 20 and the edge ring 24 of the plasma processing apparatus 1.

The heat transfer sheet, which is arranged between the electrostatic chuck 20 and the edge ring 24 and transfers the heat of the edge ring 24 to the electrostatic chuck 20, has a high dielectric material on both the upper surface and the lower surface, and has a structure of being attached to the electrostatic chuck 20 and the edge ring 24. In some cases, in such a heat transfer sheet, as a measure against the temperature variation in the edge ring 24, the adhesiveness may be increased to stabilize a thermal resistance of the contact interface in vacuum state, or the heat transfer gas may be allowed to flow between the electrostatic chuck 20 and the edge ring 24. However, if the adhesiveness of the surface of the heat transfer sheet is increased, the heat transfer sheet is less likely to be peeled off from the edge ring 24 or the electrostatic chuck 20 when the heat transfer sheet is replaced, and thus, the maintainability is deteriorated.

Thus, it is considered to use a heat transfer sheet having no adhesiveness in order to improve maintenance work. However, in this case, in order to secure the adhesion between the heat transfer sheet, the electrostatic chuck 20, and the edge ring 24, it is necessary to apply a contact pressure to the thermal conductive member 25. For example, in a case where the adhesion is secured by interposing a clamp between these members, expansion and contraction of the electrostatic chuck 20 and the edge ring 24 by the heat are repeated by inputting the heat from the plasma in every process of the substrate W in a state where the clamp interposes the heat transfer sheet. This is due to the difference in linear expansion between the electrostatic chuck 20 and the edge ring 24. Accordingly, peeling of the heat transfer sheet, loosening of the clamping force, and the like occur. For this reason, the thermal resistance of the contact interface between the heat transfer sheet and the electrostatic chuck 20 and between the heat transfer sheet and the edge ring 24 becomes unstable, or variations in pasting of the heat transfer sheet at the time of installation of the heat transfer sheet or the clamp fastening force occur. Accordingly, in some cases, variations in the thermal resistance of the contact interface of the heat transfer sheet may occur. As a result, a difference in temperature occurs between the electrostatic chuck 20 and the heat transfer sheet and between the edge ring 24 and the heat transfer sheet.

Therefore, in the embodiment, the thermal conductive member 25 that can stably transfer heat and can be easily maintained is provided. For this reason, the thermal conductive member 25 according to the embodiment uses a high dielectric material so as to apply the contact pressure by the electrostatic attraction force. Then, the thermal resistance of the contact interface is controlled by controlling the HV voltage applied to the electrode 21 for edge ring. Accordingly, by flexibly changing the contact pressure with respect to the thermal conductive member 25 and controlling the thermal resistance of the contact interface, it is possible to follow changes of wear and the like of the edge ring 24 over time, and it is possible to stably control the temperature of the edge ring 24.

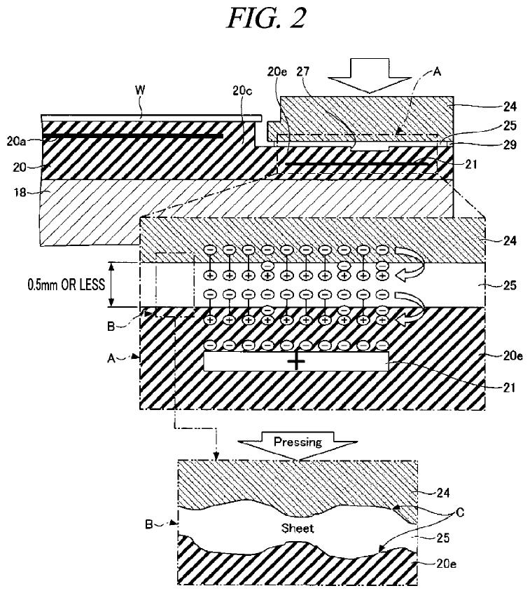

FIG. 2 is an enlarged view of a portion A of an interface of the thermal conductive member 25 and is a view for describing polarization of the thermal conductive member 25. In the plasma processing apparatus 1, the edge ring 24 is a component of which temperature is controlled. The thermal conductive member 25, which is a polymer sheet having a high permittivity, is arranged between the edge ring 24 and the electrostatic chuck 20, and the HV voltage is applied to the electrode 21 for edge ring inside the electrostatic chuck 20. In FIG. 2, a positive HV voltage is applied to the electrode 21 for edge ring. In the electrostatic chuck 20, negative charges move to the electrode 21 for edge ring side, and thus, a large amount of positive charges exist on the upper surface of the electrostatic chuck 20. With respect to positive charges on the upper surface of the electrostatic chuck 20, negative charges are attracted to the lower surface of the thermal conductive member 25, and positive charges move to the upper surface of the thermal conductive member 25. Accordingly, the inside of the thermal conductive member 25 is polarized by the Coulomb force, and negative charges are attracted into the lower surface of the edge ring 24. As a result, the contact pressure is generated between the upper surface of the electrostatic chuck 20 and the lower surface of the thermal conductive member 25 and between the upper surface of the thermal conductive member 25 and the lower surface of the edge ring 24. By controlling the HV voltage to the electrode 21 for edge ring in this state, the contact pressure between the members is changed. Accordingly, as schematically illustrated in a portion B that is a further enlarged portion of a portion of the interface of the thermal conductive member 25, values C (illustrated in the enlarged portion B) of the thermal resistance of the interfaces between the edge ring 24 and the thermal conductive member 25 and between the electrostatic chuck 20 and the thermal conductive member 25 can be arbitrarily changed. As a result, the temperature of the edge ring 24 can be maintained and managed at an appropriate temperature.

Furthermore, the HV voltage applied to the electrode 21 for edge ring is controlled to generate a desired Coulomb force, and thus, the thermal conductive member 25 does not need to have adhesiveness in order to control the values of the thermal resistance of the interfaces between the edge ring 24 and the thermal conductive member 25 and between the electrostatic chuck 20 and the thermal conductive member 25. Accordingly, it is possible to provide the thermal conductive member 25 that stably transfers heat and is easily maintained.

[High Dielectricization of Thermal Conductive Member]

In a case where the thermal conductive member 25 is made of silicon, the permittivity εᵣ of silicon is 6, so that the polarization illustrated in FIG. 2 does not occur inside the thermal conductive member 25. Therefore, in a case where the thermal conductive member 25 is made of silicon, the electrostatic attraction by the electrostatic chuck 20 may not be sufficiently performed.

Therefore, it is preferable that the permittivity εᵣ of the thermal conductive member 25 is set to about 9. For this reason, the thermal conductive member 25 is formed by adding a high dielectric material to silicon and alumina (Al₂O₃). As an example of the high dielectric material, fillers of titanium oxide and barium titanate can be exemplified.

However, the thermal conductive member 25 is not limited to this, and alumina (Al₂O₃) and a high dielectric material may be allowed to be contained in silicon carbide that is harder than silicon. In addition, in the thermal conductive member 25, alumina (Al₂O₃) and a high dielectric material may be allowed to be contained in tungsten carbide (WC) which is harder than silicon.

[Thickness of Thermal Conductive Member]

It is preferable that the thickness of the thermal conductive member 25 is 0.5 mm or less. The reason will be described.

The electrostatic attraction force between the edge ring 24 and the thermal conductive member 25 is expressed by Formula (1) shown below. In addition, the electrostatic attraction force is proportional to the contact pressure.

$${F}_{1} = \frac{1}{2} \cdot {ɛ}_{r}^{2} {ɛ}_{0} \cdot {( \frac{V}{d} )}^{2} \cdot {S}_{1} \qquad ( 1 )$$

Herein, εᵣ is the permittivity of the thermal conductive member 25, ε₀ is the permittivity of the vacuum, V is the HV voltage applied to the electrode 21 for edge ring, d is the distance from the electrode 21 for edge ring to the surface with which the edge ring 24 and the substrate support 14 are in contact, and S₁ is the area of the surface with which the edge ring 24 and the substrate support 14 are in contact.

In addition, the electrostatic attraction force between the electrostatic chuck 20 and the thermal conductive member 25 is expressed by Formula (2) shown below.

$${F}_{2} = \frac{1}{2} \cdot {ɛ}_{r}^{2} {ɛ}_{0} \cdot {( \frac{V}{{d}_{1} + {ɛ}_{r} {d}_{2 }} )}^{2} \cdot {S}_{2} \qquad ( 2 )$$

Herein, d₁ is a distance from a groove 27 (refer to FIG. 2) for the flow channel of the heat transfer gas to the electrode 21 for edge ring, d₂ is a depth of groove, and S₂ is an area of groove.

In a state where the edge ring 24 is electrostatically attracted to the electrostatic chuck 20 and the heat transfer gas (such as He gas) is supplied to the groove 27 to cool the edge ring 24, in a case where the thermal conductive member 25 (sheet) is not interposed, when the edge ring 24 is removed from the electrostatic chuck 20, an electrostatic attraction force of 291 N is applied based on Formulae (1) and (2). On the other hand, for example, if a thermal conductive member 25 of 0.3 mm is inserted between the edge ring 24 and the electrostatic chuck 20, the thickness between the edge ring 24 and the electrostatic chuck 20 becomes 0.8 mm, and thus, the attraction force is reduced down to 142 N.

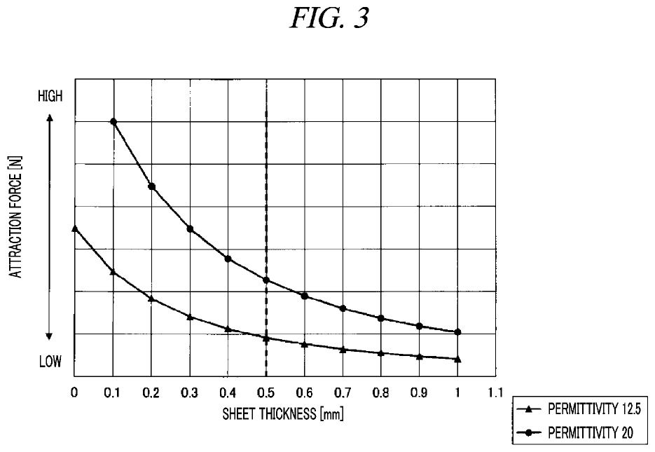

Therefore, the results obtained by changing the permittivity εᵣ of the thermal conductive member 25 from 12.5 to 20 and measuring the attraction force between the edge ring 24 and the electrostatic chuck 20 when the thickness of the thermal conductive member 25 is changed are illustrated in FIG. 3. FIG. 3 is a diagram illustrating an example of the relationship between the thickness of the thermal conductive member 25 and the attraction force according to the embodiment. The horizontal axis of FIG. 3 represents the thickness of the thermal conductive member 25, and the vertical axis represents the attraction force between the edge ring 24 and the electrostatic chuck 20.

As a result of FIG. 3, when the permittivity εᵣ of the thermal conductive member 25 is changed from 12.5 to 20, the attraction force is increased. As a result, as compared with a case where there is no thermal conductive member 25, the attraction forces become about the same. As the permittivity εᵣ of the thermal conductive member 25 becomes large, the attraction force is increased. Therefore, by setting the permittivity εᵣ of the thermal conductive member 25 to 20 or more, a desired attraction force can be obtained in the configuration having the thermal conductive member 25. However, even when the permittivity εᵣ of the thermal conductive member 25 is set to 20 or more, if the thickness thereof exceeds 0.5 mm, in some cases, the attraction force falls below the allowable range as compared with the case without the thermal conductive member 25. From the description above, if the thickness of the thermal conductive member 25 is larger than 0.5 mm, the electrostatic attraction force is reduced, and even if the HV voltage is applied to the electrode 21 for edge ring, electrostatic attraction between the edge ring 24 and the thermal conductive member 25 and between the electrostatic chuck 20 and the thermal conductive member 25 may not be sufficiently performed. For this reason, it is preferable that the thickness of the thermal conductive member 25 is 0.5 mm or less.

In the description above, the groove 27 serving as the flow channel of the heat transfer gas is provided, but the groove 27 may be omitted. In this case, d₁+εᵣd₂ in Formula (2) can be replaced with d. Also in this case, it is preferable that the thickness of the thermal conductive member 25 is 0.5 mm or less in consideration of the decrease in the attraction force.

### Modified Example of Thermal Conductive Member and Electrostatic Chuck

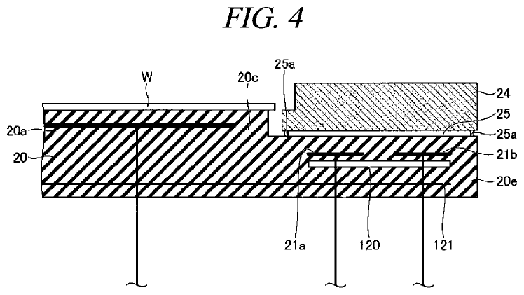

Modified Example of configurations of the thermal conductive member 25 and the electrostatic chuck 20 will be described in brief with reference to FIG. 4. FIG. 4 is a diagram illustrating Modified Example of the configurations of the thermal conductive member 25 and the electrostatic chuck 20 according to the embodiment.

It is preferable that the portion of the thermal conductive member 25 exposed to the plasma is coated with a film 25a having plasma resistance. As an example of coating of the film 25a having plasma resistance, nickel plating coating can be exemplified. Accordingly, the portion of the thermal conductive member 25 exposed to the plasma can be protected from the plasma. However, in order to maintain the flexibility of the thermal conductive member 25, at least the upper surface and the lower surface of the thermal conductive member 25 are not coated with the film 25a having plasma resistance. In the example of FIG. 4, the side surface of the thermal conductive member 25 is a portion exposed to plasma, and the upper surface and the lower surface of the thermal conductive member 25 are not exposed to plasma. Therefore, the side surface of the thermal conductive member 25 is coated with the film 25a having plasma resistance.

Due to the difference in linear expansion between the edge ring 24 and the electrostatic chuck 20 caused by heat input from the plasma, friction may occur between the edge ring 24 and the thermal conductive member 25 and between the electrostatic chuck 20 and the thermal conductive member 25. At this time, when the upper surface and the lower surface of the thermal conductive member 25 are coated with the film 25a, the surfaces become harder than in the case that the film 25a is not coated thereon. Therefore, by coating the upper surface and the lower surface of the thermal conductive member 25 with the film 25a, the probability that the surfaces of the edge ring 24 and the electrostatic chuck 20 are damaged by friction is increased. Therefore, in the embodiment, at least the upper surface and the lower surface of the thermal conductive member 25 are not coated with the film 25a, and only the portion exposed to the plasma is coated. Accordingly, it is possible to maintain the flexibility of the thermal conductive member 25, and it is possible to avoid the damage to the edge ring 24 and the electrostatic chuck 20 due to the friction.

In the embodiment illustrated in FIGS. 1 and 2, the number of the electrodes 21 for edge ring is one (unipolar). On the other hand, as illustrated in Modified Example of FIG. 4, the electrode 21 for edge ring may have a plurality of electrodes 21a and 21b (bipolar). In this case, the HV voltage for electrostatically attracting the edge ring is applied to the electrodes 21a and 21b, and the polarities of the HV voltage applied to the electrodes 21a and 21b may be the same or may be different.

In addition, a cooling medium flow channel 120 and/or a heater 121 may be provided in a region facing the edge ring 24 inside the electrostatic chuck 20. By combining the thermal conductive member 25 with the cooling medium flow channel 120 and/or the heater 121, the temperature of the edge ring 24 can be quickly controlled to a more appropriate temperature.

[Voltage Control Method]

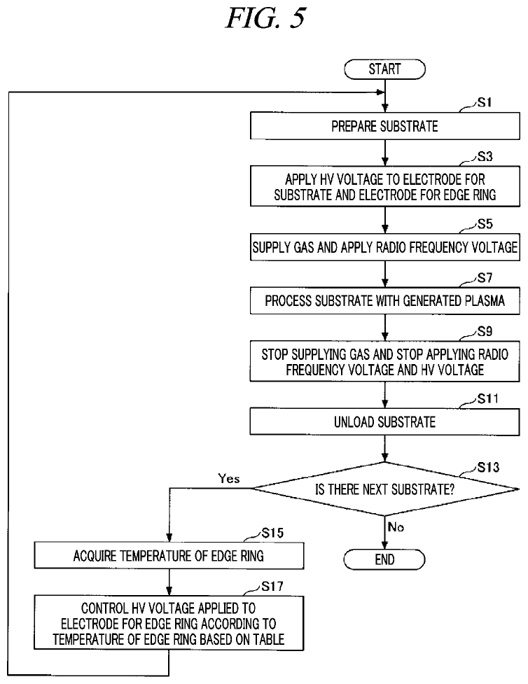

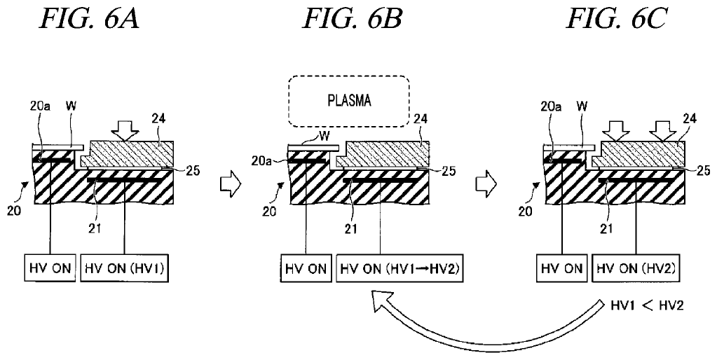

Next, a voltage control method of the electrode 21 for edge ring using the plasma processing apparatus 1 in which the thermal conductive member 25 described above is arranged will be described with reference to FIGS. 5 and 6A to 6C. FIG. 5 is a flowchart illustrating an example of the voltage control method according to the embodiment. FIGS. 6A to 6C are diagrams for describing the voltage control method according to the embodiment.

The voltage control method according to the embodiment is performed in the plasma processing apparatus 1. The plasma processing apparatus 1 includes the electrostatic chuck 20 on which the substrate W is mounted in the chamber 10 that provides the plasma processing space 10s, the edge ring 24 which is provided on the electrostatic chuck 20 so as to surround a region where the substrate W is mounted and at least a portion of which is made of a conductive member, and the electrode 21 for edge ring to which an HV voltage for electrostatically attracting the edge ring 24 is applied in a region inside the electrostatic chuck 20 corresponding to the edge ring 24.

The voltage control method according to the embodiment includes a step of processing the substrate W, a step of acquiring the temperature of the edge ring 24, and a step of referring to the storage unit 202 that stores the correlation between the temperature of the edge ring 24 and the HV voltage applied to the electrode 21 for edge ring and controlling the HV voltage applied to the electrode 21 for edge ring according to the acquired temperature of the edge ring 24. The voltage control method according to the embodiment is controlled by the control unit 201. A specific voltage control method will be described below.

When the process of FIG. 5 is started, the control unit 201 prepares the substrate W (step S1). Next, the control unit 201 applies the set HV voltage to each of the electrode 20a for substrate and the electrode 21 for edge ring (step S3). For example, the control unit 201 sets the value of HV voltage applied to the electrode 21 for edge ring to “HV1” when the temperature of the edge ring 24 is “T₁”, based on the information indicating the correlation between the temperature of the edge ring 24 and the HV voltage stored in the table TB illustrated in FIG. 1. For example, as illustrated in FIG. 6A, the HV voltage of HV1 is applied to the electrode 21 for edge ring at this time.

Next, the control unit 201 supplies gas from the gas supply unit GS and applies a radio frequency voltage from the first radio frequency power supply 48 and the second radio frequency power supply 90 (step S5). However, the radio frequency voltage may be applied only from the first radio frequency power supply 48.

Next, the control unit 201 generates plasma from the gas with the radio frequency voltage and processes the substrate W with the generated plasma (step S7). For example, as illustrated in FIG. 6B, plasma is generated from the gas, and the substrate W is processed by the generated plasma.

Next, the control unit 201 stops the gas supply and stops the application of the radio frequency voltage and the HV voltage (step S9). Next, the control unit 201 unloads the processed substrate W (step S11), the control unit determines whether there is a next substrate W (step S13), and in a case where the control unit determines that there is no next substrate W, the control unit ends this process.

In a case where the control unit determines in step S13 that the next substrate W exists, the control unit 201 acquires the temperature of the edge ring 24 measured by the temperature sensor 29 (step S15). Next, the control unit 201 refers to the storage unit 202 and controls the HV voltage applied to the electrode 21 for edge ring according to the acquired temperature of the edge ring 24 based on the information indicating the correlation stored in the table TB (step S17). Next, returning to step S1, the control unit 201 prepares the next substrate W and processes the next substrate W by performing the processes subsequent to step S3. The control unit 201 repeats this operation until the control unit determines in step S13 that there is no next substrate.

For example, when the acquired temperature of the edge ring 24 is “T₂”, the control unit 201 sets the HV voltage applied to the electrode 21 for edge ring to “HV2” based on the information indicating the correlation stored in the table TB. For example, as illustrated in FIG. 6C, the HV voltage of HV2 is applied to the electrode 21 for edge ring at this time. At this time, due to the relationship of HV1<HV2, the electrostatic attraction force (Coulomb force) is increased, and thus, the contact pressure between the edge ring 24 and the thermal conductive member 25 and between the electrostatic chuck 20 and the thermal conductive member 25 is increased. As a result, it becomes easier to stably transfer heat between the edge ring 24 and the thermal conductive member 25 and between the electrostatic chuck 20 and the thermal conductive member 25, and thus, the temperature of the edge ring 24 can be maintained and adjusted to more appropriate temperature. In addition, since the thermal conductive member 25 is non-adhesive, it is possible to easily perform maintenance.

It should be considered that the thermal conductive member, the plasma processing apparatus, and the voltage control method according to the embodiments disclosed this time are examples in all respects and are not restrictive. The above-described embodiments can be modified and improved in various forms without departing from the scope and spirit of the appended claims. The matters described in the above-described plurality of embodiments can have other configurations as long as the configurations do not conflict with each other, and the matters can be combined with each other as long as the configuration do not conflict.

The plasma processing apparatus of the disclosure can be applied to any type of an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, and a helicon wave plasma (HWP) apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

What is claimed is:

1. A thermal conductive member used in a plasma processing apparatus, the plasma processing apparatus comprising:
a first electrostatic chuck on which a substrate is mounted in a chamber that provides a plasma processing space;
a second electrostatic chuck on an outer periphery of the first electrostatic chuck;
an edge ring which is provided on the second electrostatic chuck so as to surround a region on which the substrate is mounted and at least a portion of which is made of a conductive member; and
an electrode for edge ring to which a voltage for electrostatically attracting the edge ring is applied in a region corresponding to the edge ring inside the second electrostatic chuck,
wherein the thermal conductive member is arranged between the second electrostatic chuck and the edge ring.

2. The thermal conductive member according to claim 1,
wherein the thermal conductive member has no adhesiveness.

3. The thermal conductive member according to claim 1,
wherein a permittivity of the thermal conductive member is 20 or more.

4. The thermal conductive member according to claim 3,
wherein a thickness of the thermal conductive member is 0.5 mm or less.

5. The thermal conductive member according to claim 1,
wherein the thermal conductive member is formed by adding a high dielectric material to silicon and alumina.

6. The thermal conductive member according to claim 1,
wherein a portion of the thermal conductive member exposed to plasma is coated with a film having plasma resistance.

7. The thermal conductive member according to claim 1,
wherein the electrode for edge ring has a plurality of electrodes and is configured to be applied with a voltage for electrostatically attracting the edge ring.

8. The thermal conductive member according to claim 1,
wherein the thermal conductive member is formed by adding a high dielectric material to silicon carbide or tungsten carbide and alumina.

9. The thermal conductive member according to claim 1,
wherein a cooling medium flow channel and/or a heater is provided in a region of the second electrostatic chuck that faces the edge ring.

10. A plasma processing apparatus comprising:
a first electrostatic chuck on which a substrate is mounted in a chamber that provides a plasma processing space;
a second electrostatic chuck on an outer periphery of the first electrostatic chuck;
an edge ring which is provided on the second electrostatic chuck so as to surround a region on which the substrate is mounted and at least a portion of which is made of a conductive member;
a thermal conductive member which is arranged between the second electrostatic chuck and the edge ring; and
an electrode for edge ring to which a voltage for electrostatically attracting the edge ring is applied in a region corresponding to the edge ring inside the second electrostatic chuck.

11. A voltage control method performed in a plasma processing apparatus, the plasma processing apparatus comprising:
a first electrostatic chuck on which a substrate is mounted in a chamber that provides a plasma processing space;
a second electrostatic chuck on an outer periphery of the first electrostatic chuck;
an edge ring which is provided on the second electrostatic chuck so as to surround a region on which the substrate is mounted and at least a portion of which is made of a conductive member; and
an electrode for edge ring to which a voltage for electrostatically attracting the edge ring is applied in a region corresponding to the edge ring inside the second electrostatic chuck, the voltage control method comprising:
processing the substrate;
acquiring a temperature of the edge ring; and
referring to a storage unit that stores information indicating correlation between the temperature of the edge ring and the voltage applied to the electrode for edge ring and controlling the voltage to be applied to the electrode for edge ring according to the acquired temperature of the edge ring.
